(19) United States
(12) Patent Application Publication
(10) Pub. No.: US 2008/0048779 A1
(43) Pub. Date: Feb. 28, 2008

(54) ACTIVE EMI SUPPRESSION CIRCUIT

(76) Inventors: Philip John Crawley, Sacramento, CA (US); Amit Gattani, Roseville, CA (US); Jun Cai, Mather, CA (US)

Correspondence Address: KOESTNER BERTANI LLP, 2192 Martin St., Suite 150, Irvine, CA, 92612, US

(21) Appl. No.: 11/872,630

(22) Filed: Oct. 15, 2007

Related U.S. Application Data
(63) Continuation-in-part of application No. 11/435,672, filed on May 16, 2006.

(51) Int. Cl. H04L 25/00; H03F 3/45

(52) U.S. Cl. 330/258

(57) ABSTRACT

A network device comprises an interface coupling an electronic device to a differential pair of signal lines, and an active common mode suppression circuit coupled to the interface in parallel to differential signal lines of the electronic device.

### CROSS REFERENCE TO RELATED APPLICATIONS

This application claims priority as a Continuation-in-Part (CIP) and incorporates herein by reference in its entirety for all purposes, U.S. patent application Ser. No.: 11/435,672 entitled “ACTIVE EMI SUPPRESSION CIRCUIT,” by Amit Gattani, et al. filed May 16, 2006.

### BACKGROUND

Many networks such as local and wide area networks (LAN/WAN) structures are used to carry and distribute data communication signals between devices. Various network elements include hubs, switches, routers, and bridges, peripheral devices, such as, but not limited to, printers, data servers, desktop personal computers (PCs), portable PCs and personal data assistants (PDAs) equipped with network interface cards. Devices that connect to the network structure use power to enable operation. Power of the devices may be supplied by either an internal or an external power supply such as batteries or an AC power via a connection to an electrical outlet.

Some network solutions can distribute power over the network in combination with data communications. Power distribution over a network consolidates power and data communications over a single network connection to reduce installation costs, ensures power to network elements in the event of a traditional power failure, and enables reduction in the number of power cables, AC to DC adapters, and/or AC power supplies which may create fire and physical hazards. Additionally, power distributed over a network such as an Ethernet network may function as an uninterruptible power supply (UPS) to components or devices that normally would be powered using a dedicated UPS.

Additionally, network appliances, for example voice-over-Internet-Protocol (VOIP) telephones and other devices, are increasingly deployed and consume power. When compared to traditional counterparts, network appliances use an additional power feed. One drawback of VOIP telephony is that in the event of a power failure the ability to contact emergency services via an independently powered telephone is removed. The ability to distribute power to network appliances or circuits enable network appliances such as a VOIP telephone to operate in a fashion similar to ordinary analog telephone networks currently in use.

Distribution of power over Ethernet (PoE) network connections is in part governed by the Institute of Electrical and Electronics Engineers (IEEE) Standard 802.3 and other relevant standards, standards that are incorporated herein by reference. However, power distribution schemes within a network environment typically employ cumbersome, real estate intensive, magnetic transformers. Additionally, power over Ethernet (PoE) specifications under the IEEE 802.3 standard are stringent and often limit allowable power.

Common-mode interference (CMI) is interference that appears on both signal and circuit return leads, or terminals of a measuring circuit, and ground. CMI is traditionally handled by sensing common-mode noise and feeding the noise negatively into an object that creates the signals. Another technique for handling CMI involves applying both signal and signal return to the primary winding of a transformer with the signal taken from the secondary winding. Differential signals on the primary cause current in the primary and thus induce voltage in the secondary. In a push-pull technique, a signal transformer may have a center-tapped primary to ground with the signal and signal return operating as a balanced line, raising resistance to signals on ground due to ground-loop induction and ground circuit resistance.

### SUMMARY

According to an embodiment of a network device, an interface couples an electronic device to a differential pair of signal lines and an active common mode suppression circuit is coupled to the interface in parallel to differential signal lines of the electronic device.

### BRIEF DESCRIPTION OF THE DRAWINGS

Embodiments of the invention relating to both structure and method of operation may best be understood by referring to the following description and accompanying drawings:

FIG. 1 is a schematic block and circuit diagram showing an embodiment of a network device that includes a common mode suppression circuit;

FIG. 2 is a schematic block and circuit diagram showing an embodiment of a traditional choke that may be used in conjunction with an Ethernet physical layer (PHY);

FIG. 3 is a schematic circuit and block diagram depicting an example of system noise coupling paths for emissions that may arise in a network device;

FIG. 4 is a schematic circuit diagram showing an example embodiment of a common mode suppression circuit that can be used in a network device such as the network device depicted in FIG. 1;

FIG. 5 is a pictorial diagram illustrating an embodiment of a network device comprising an integrated circuit package comprising a plurality of integrated circuit (IC) pins coupled to an active mode suppression circuit;

FIG. 6 is a schematic block diagram depicts another embodiment of a network device that implements active electromagnetic interference (EMI) suppression;

FIG. 7 is a schematic circuit diagram illustrating a common mode suppression circuit with additional detail of the circuit and further description of the signal path; and

FIG. 8 is a schematic block and circuit diagram showing an embodiment of a programmable output stage.

### DETAILED DESCRIPTION

In an illustrative architecture of a common-mode suppression circuit, a common-mode suppression amplifier is coupled to output lines of an electronic device. An active common mode suppression circuit is coupled in parallel to transmit and receive differential signal lines connecting an electronic device module and a network connector. In a transformer-less configuration, the circuit can replace electromagnetic interference (EMI) suppression chokes that are included in modern Ethernet transformers.

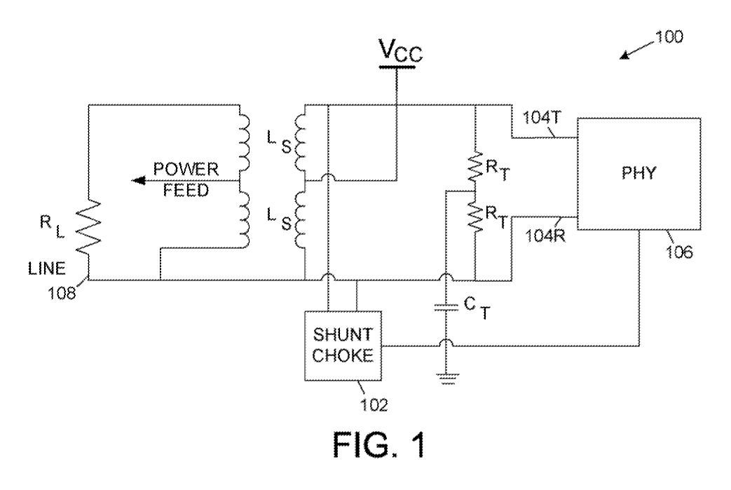

Referring to FIG. 1, a schematic block and circuit diagram illustrates an embodiment of a network device 100 comprising an interface 101 coupling an electronic device 106 to a differential pair of signal lines 104T, 104R, and an active common mode suppression circuit 102 coupled to the interface 101 in parallel to differential signal lines 104T, 104R of the electronic device 106.

The common mode suppression circuit 102 may be described functionally as a shunt choke or choke. The common mode suppression circuit (CMS) 102 is connected in parallel to the same wires 104T, 104R as the electronic device 106 whereby the shunt choke terminology is descriptive of the parallel connection. The common mode suppression circuit 102 operates as a functional block, coupled in parallel to the signal lines 104T, 104R, that supplies a very low common mode impedance termination. Accordingly, within a broad range of frequencies common mode noise in the system is absorbed by the common mode suppression circuit 102. In combination with an inherent common-mode noise rejection capability of the transformer, the active suppression circuit can assist system compliance with FCC Part 15 Class B compliance.

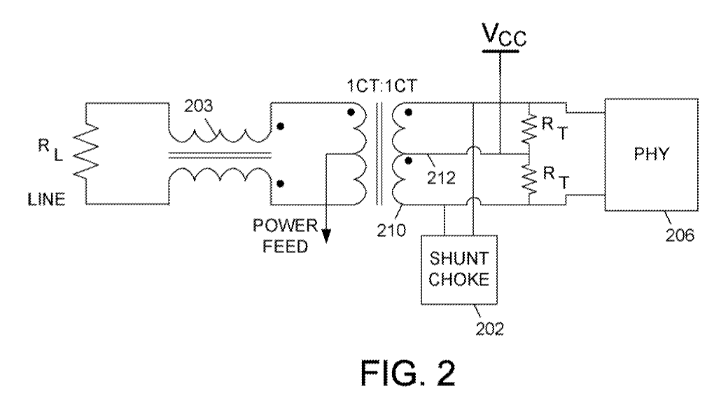

The common mode suppression circuit 102 performs aspects of a traditional choke 202 that may be used in conjunction with an Ethernet PHY 206 as shown in FIG. 2. The Ethernet PHY 206 has signal lines coupled to a traditional transformer 210. The choke 202 is depicted as horizontal windings coupled to the transformer 210. The common mode suppression circuit 102 depicted in FIG. 1 performs aspects of the choke functionality in active circuitry. The common mode suppression circuit 102 is configured to interface to standard Ethernet PHY blocks that are traditionally used with transformer-based network devices. Standard Ethernet PHY blocks have either Class-A or Class-B drivers that use the transformer center-tap 212 for direct current (DC) biasing. The center tap 212 of the transformer 210 thus sets the DC voltage for the lines 104T and 104R. In a typical implementation output common mode DC voltage of the PHY can vary in a range up to the supply voltage Vcc, for example Vcc can be 3.3V, 2.5V, 1.8V, or any voltage desired by the Ethernet PHY manufacturer. The PHY output voltage swing Vout_swing, which is derived from the common mode DC voltage, can also vary greatly, for example from 0.85V to 5.0V depending on supplied power and Ethernet type, for example 10 baseT or Fast Ethernet (100baseT), or Gigabit Ethernet (1000 baseT).

In a network device configuration such as shown in FIG. 2 that includes a transformer 212, the transformer 212 can be powered-on and powered-off in some applications. The shunt choke 202 suppresses EMI in response to perturbations in power through the transformer 212.

Referring again to FIG. 1, in some embodiments the electronic device 106 can be an Ethernet Physical Layer (PHY) and the interface 101 can be an Ethernet interface that couples a differential pair network connector to an Ethernet physical layer (PHY). An example of typical constraints imposed by usage of the Ethernet PHY include an external load at high frequency is limited by R_{T}, for example 50 Ω, Ethernet common mode termination plus parasitic capacitance at the node. The R_{T} Ethernet common mode termination, depicted as R_{T} resistors at input lines to the Ethernet PHY, in combination with parasitic capacitors that typically exist in the system add on the order of 20 pF of shunt loading. In a specific design example, common mode rejection ratio may be specified to a frequency of 100 MHz. Consequently, a suitable common mode noise suppression circuit may be specified to include a reasonably high loop gain at 100 MHz. The specification is addressed by implementing a reasonably high loop gain in the specified frequency range. The common mode noise suppression circuit design includes a fundamental trade-off between loop stability and common mode rejection ratio (CMRR) performance. Accordingly, the shunt choke 102 is configured to have suitable high frequency performance to address the loading due to the common mode resistance and parasitic capacitance. In the illustrative example, the loading by a resistance of R_{T}, for example 50 Ω, and parasitic capacitance of 20 pF results in a frequency behavior including a pole at 160 MHz in combination with a performance specification imposed on the choke of suitable performance up to 100 MHz. Thus, in the illustrative example, the design challenge is to configure the common mode suppression circuit 102 to have very good rejection at 100 MHz when limited by a 160 MHz pole.

With regard to stability, an analog closed loop can have stable and nonstable operating zones. For example in a configuration with a pole at 160 MHz, good common mode rejection performance imposes specification of a high gain at 100 MHz, contrary to a specification to attain loop stability. In an illustrative design, stability criteria may be addressed by enabling the output stage to roll-off while the input stage maintains high gain.

The interface 101 and associated common mode suppression circuit 102 can be used in applications with a transformer, such as an Ethernet transformer, or with applications that omit a transformer. In various implementations and embodiments a transformer can be included for emitted, for example the interface 101 can be a generic differential interface such as Universal Serial Bus (USB), Institute of Electrical and Electronics Engineers (IEEE) 1394, High-Definition Multimedia Interface (HDMI), DisplayPort standard as defined by Video Electronics Standards Association (VESA), Digital Visual Interface (DVI), audio signals, and other interfaces. In such generic interfaces, the system may not include a transformer.

In various embodiments, the interface 101 can be constructed for compatibility with various standards. For example, the interface 101 can be implemented based on n-channel metal oxide semiconductor (NMOS) devices, p-channel metal oxide semiconductor (PMOS) devices, or a combination of NMOS and PMOS devices. An implementation of the interface 101 with a shunt choke 102 that includes only an NMOS output stage conserves circuit area and improves electrostatic discharge (ESD) performance.

The interface 101 and common mode suppression circuit 102 can be used in any suitable network device configuration. For example, the interface 101 and common mode suppression circuit 102 can be used with line transformers or direct connect interfaces.

In various Ethernet embodiments, the common mode suppression circuit can be implemented on either the line side or the device side of the Ethernet transformer. For example, isolated powering can be used to power the device on the line side by using techniques disclosed in U.S. patent application Ser. No.: 11/562,899 entitled “POWER OVER ETHERNET WITH ISOLATION,” by Sajol Ghoshal, filed Nov. 22, 2006; U.S. patent application Ser. No.: 11/674,395 entitled “SIGNAL COMMUNICATION ACROSS AN ISOLATION BARRIER,” by Timothy A. Dhuyvetter, et al., filed on Feb. 13, 2007; U.S. patent application Ser. No.: 11/627,345 entitled “PARTITIONED SIGNAL AND POWER TRANSFER ACROSS AN ISOLATION BARRIER,” by Philip John Crawley, et al., filed on Feb. 13, 2007; U.S. patent application Ser. No.: 11/683,985 entitled “DIGITAL ISOLATOR,” by Philip John Crawley, et al., filed on Mar. 8, 2007; U.S. patent application Ser. No.: 11/747,797 entitled “DIGITAL ISOLATOR INTERFACE WITH PROCESS TRACKING,” by Philip John Crawley, et al., filed on May 11, 2007; and U.S. patent application Ser. No.: 11/682,823 entitled “NETWORK DEVICES WITH SOLID STATE TRANSFORMER AND CLASS AB OUTPUT STAGE FOR ACTIVE EMI SUPPRESSION AND TERMINATION OF OPEN-DRAIN TRANSMIT DRIVERS OF A PHYSICAL DEVICE,” by Jun Cai, et al. filed Mar. 6, 2007 which are incorporated by reference into the present application in their entirety for all purposes.

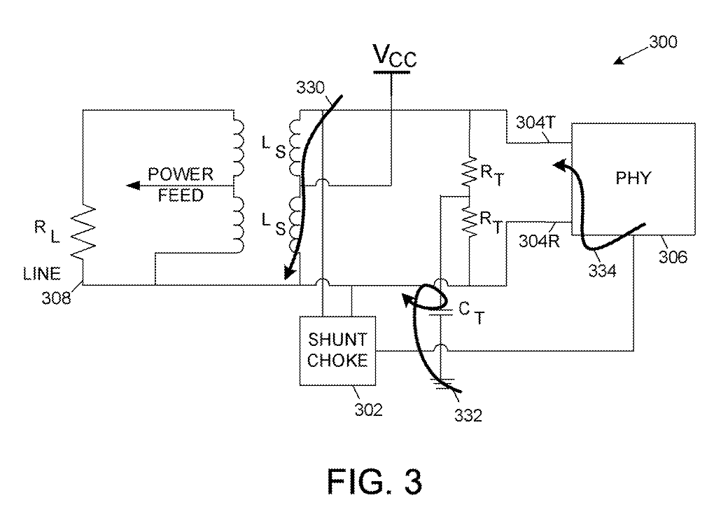

Referring to FIG. 3, a schematic circuit and block diagram illustrates an example of system noise coupling paths for emissions that may arise in a network device 300. The network device 300 comprises an active common mode suppression circuit 302 that is configured to absorb common mode noise by forming a low impedance path from an output terminal of an electronic device 306, for example an Ethernet Physical layer (PHY) module, to ground. An Ethernet PHY module 306 has an output common mode level of the Ethernet PHY module 306 can vary up to V_{CC}. The output load condition is highly variable. Thus, the choke 302 is configured for suitable performance in the megahertz to gigahertz range. Pin wires, supply inductors, and parasitic capacitances all may form noise coupling paths to be addressed by the shunt choke 302.

The illustrative network device 300 implements a shunt technique for EMI suppression that improves differential to common mode conversion and improves EMI suppression performance. The active common mode suppression circuit 302 suppresses common mode noise generated as a result of differential-to-common mode conversion due to transformer imperfections.

Arrows are superimposed on FIG. 3 showing possible sources of common mode noise. Noise can possibly propagate from the Vcc power supply path 330, from the ground path 332, and from the electronic device 334. The choke shunt 302 reduces or minimizes noise sources 330 through the center tap of the transformer, and noise 332 from ground. The choke shunt 302 also addresses noise 334 from the device. For example, noise 334 from the PHY 306 can be the greatest noise source, including clock frequency and clock noise that is switched out through the device 306, and the most important noise to suppress. The function of the choke 302 is to operate as a noise absorber that chokes common mode noise and prevents transmission of common mode noise to the Ethernet twisted pair cable that in turn becomes electromagnetic interference (EMI) emission. The shunt choke 302 absorbs the common mode noise by forming a very low impedance path from the Ethernet PHY output terminals to ground so that any common mode noise follows a path of least resistance through the choke 302 to ground, thereby diverting the noise from the signal line. Supply Vcc is typically a dominant source of noise, although the noise sourced in relatively variable.

The shunt choke 302 can be designed by taking into consideration what noise sources are present, locations of the noise paths, and characteristics, source impedances and worst case conditions of the noise sources.

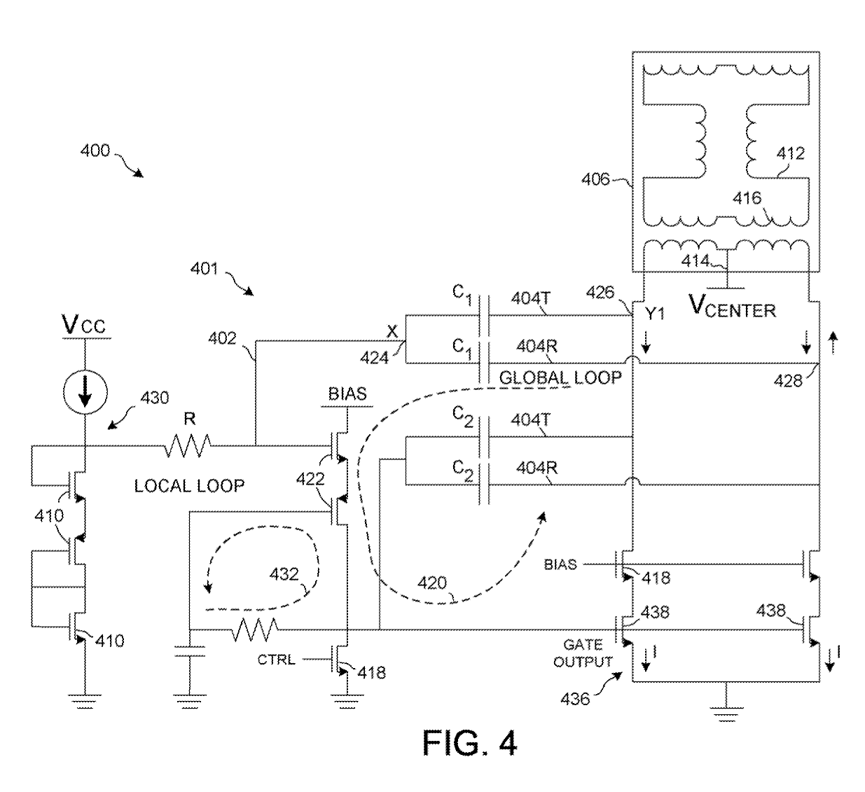

Referring to FIG. 4, a schematic circuit diagram depicts an example embodiment of a common mode suppression circuit 402 that can be used in a network device such as the network device 406 depicted in FIG. 1. The illustrative common mode suppression circuit 402 comprises one or more active output devices 410 coupled to an interface 401 and a transformer 412 coupled to the electronic device 406. The transformer 412 comprises a center tap 414 and windings 416. The active common mode suppression circuit 402 is configured to draw power from the active output devices 410 through the center tap 414 of the transformer 412.

In an illustrative embodiment, the active common mode suppression circuit 402 is configured to reduce electromagnetic interference (EMI) noise related in part to common mode noise through the transformer 412. The active common mode suppression circuit 402 can also be configured to reduce common mode impedance and short-circuit common-mode energy to a system ground.

The illustrative active common mode suppression circuit 402 includes a high-bandwidth AC-coupled feedback loop 420 that is stable when connected to the transformer 412. AC-coupling feedback is useful because feedback control does not depend on the DC value of the network lines, for example RJ-45 lines, so the circuit can operate with different DC bias conditions on the (RJ-45) line.

The active common mode suppression circuit 402 includes control devices 418 that enable programmable adjustment.

The electronic device 400 operates by coupling an electronic device 406 to a differential pair of signal lines 404T, 404R; and coupling an active common mode suppression circuit 402 in parallel to differential signal lines of the electronic device 406.

Power is drawn power from active common mode suppression circuit output devices 438 that drive signals onto the differential pair of signal lines 404T, 404R through a center tap 414 of an Ethernet transformer 412 whereby common mode impedance is reduced.

The illustrative common mode suppression circuit 402 includes a differential amplifier 422 and performs alternative current (AC) coupling sensing at a point X 424. Capacitors C1 are used to perform AC sensing. In a particular embodiment the capacitors C1 can be 0.5pF capacitors, although any suitable capacitance can be implemented according to typical circuit design constraints. The common mode suppression circuit 402 operates as a common mode circuit whereby when the transformer 412 is in a direct current (DC) condition, the circuit 402 has no gain because inductors are in a short-circuit condition. The capacitors C1 are selected for suitable performance in sensing common mode current.

The illustrative configuration of the common mode suppression circuit 402 enables a high current absorption capability that improves noise immunity. The arrangement also enables toleration of a wide differential signal swing.

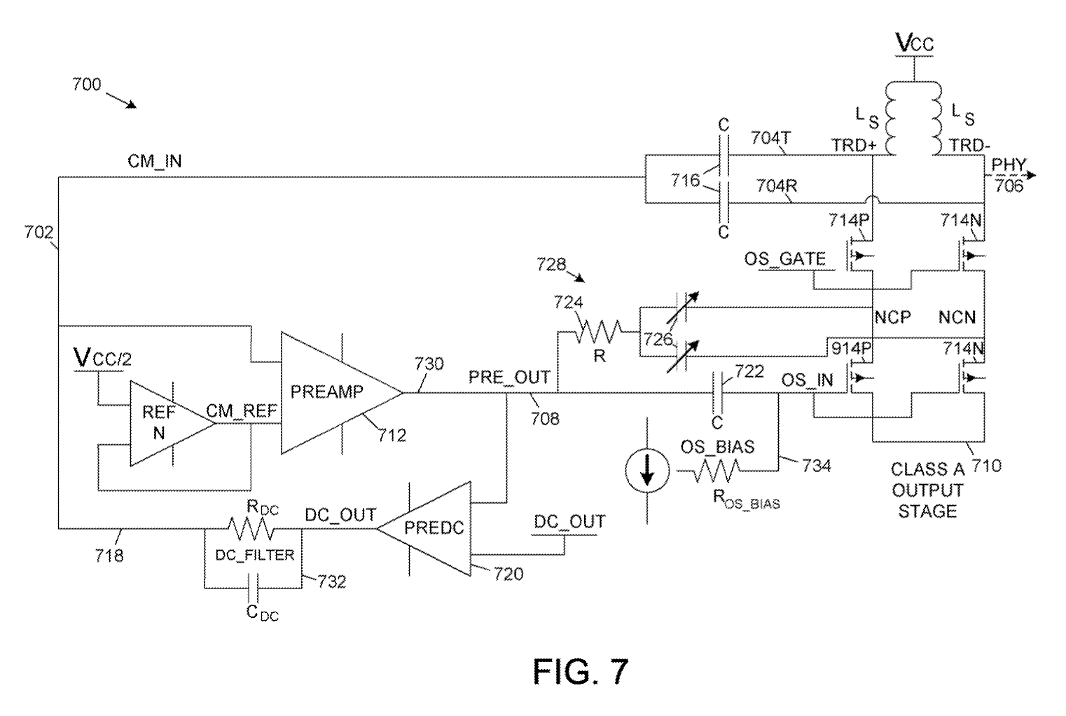

The common mode suppression circuit 402 depicted in FIG. 4 simplifies circuit structure and operation over the common mode suppression circuit 702 shown in FIG. 7 which includes multiple loops to ensure stability. In contrast, common mode suppression circuit 402 has a simplified structure wherein the capacitors C1 define a center point at point X 424 that enables differential tracking of common mode current. Differential tracking operates so that when two nodes Y1 426 and Y2 428 move up and down in opposite directions during operation, the node X 424 does not move. In contrast, when the two nodes Y1 426 and Y2 428 move in the same direction, then node X 424 moves and generates a feedback signal. The common mode suppression circuit 402 is configured so that at a DC condition, a bias circuit 430 in a bias loop 432 sets an output stage 434 to draw a fixed amount of current i, which defines a bias point and enables setting of the capacity of the common mode suppression circuit 402 to suppress common mode noise.

The common mode suppression circuit 402 can be configured taking into consideration two component parameters, loop gain and base output impedance of the active output devices 410. The global loop 420 draws a predetermined amount of current unless a common mode disturbance occurs at a frequency that is higher than a predetermined normal range of frequencies. If voltage at both active output devices 410 increases, then current at the node X 424 begins increase and the feedback loop 420 attempts to suppress the current increase at node X 424 and through operation of the local loop 432 a transient event is created on the gated output devices 410. The feedback loop operates with negative feedback which suppresses the current increase at node X 424.

The illustrative feedback loop is simple and fast, thereby improving feedback loop performance.

Capacitors C2 supply Miller compensation. Accordingly, capacitors C1 capacitors are used for common mode sensing and capacitors C2 enable Miller compensation.

The common mode suppression circuit 402 effectively functions as a two-stage operational amplifier, operational as a common mode amplifier, except a differential pair is not implemented. The illustrative common mode suppression circuit 402 operates in the manner of a common mode amplifier that has a single transistor wherein the circuit responds to disturbances in the common mode and attempts to prevent the disturbances from occurring.

The local loop 432 ensures correct DC biasing and responds quickly to disturbances. The common mode suppression circuit 402 remains quiescent with the node X 424 stable, drawing a fixed amount of current from the output load which is drawn through the transformer 412, until a disturbance occurs.

The common mode suppression circuit 402 operates as an AC-coupled loop wherein no feedback is present when the transformer 412 is at DC. The common mode suppression circuit 702 depicted in FIG. 7 includes some structural and operation complexity to attain a correct operating point. In contrast, the illustrative common mode suppression circuit 402 sets the correct operation point with increased simplicity.

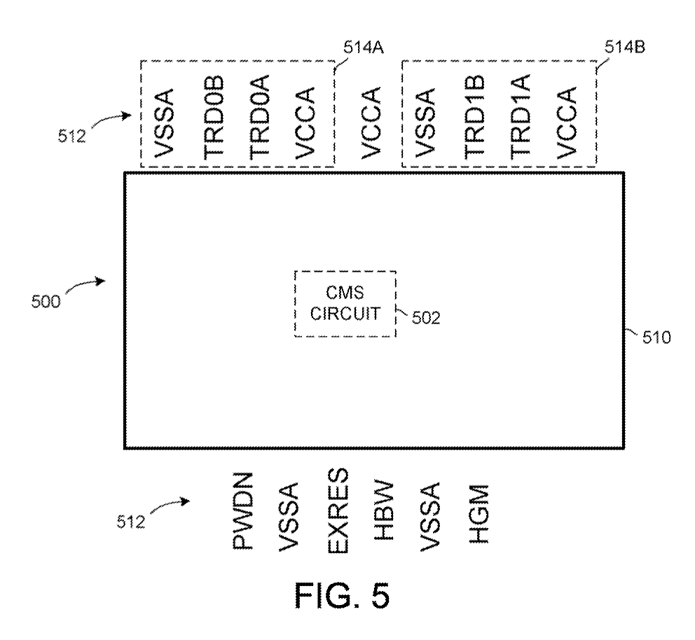

Referring to FIG. 5, a pictorial diagram illustrates an embodiment of a network device 500 comprising an integrated circuit package 510 comprising a plurality of integrated circuit (IC) pins 512 coupled to an active mode suppression circuit and arranged as at least one differential pin set 514A, 514B each comprising a negative power pin (V_{SS}), first and second differential transmit and receive line pins for coupling to the transmit and receive differential signal lines, and a power pin (V_{CC}). The integrated circuit package 510 can be used for implementing a network device 500 that includes an active common mode suppression circuit 502.

The IC package 510 can be implemented with the active common mode suppression circuit configured for programmable adjustment.

For example, the IC package 510 can be, as shown, a Quarter-size Small-Outline (QSOP) package 510 comprising multiple pins 512 arranged as first 514A and second 514B differential pin sets. Each pin set has a negative power pad (V_{SSA}), first (TRDnA) and second (TRDnA) differential transmit and receive line pins for coupling to the transmit and receive differential signal lines, and a power pin (V_{CCA}) for pin sets n=1, and n=2. Additional pins can include a power down pin (PWDN) pin, an output current gain (HGM) pin, and a global loop bandwidth (HBW) pin. The PWDN pin can be used for chip power down, as a test mode enable pin, and in a default mode designating that both channels are active. The HGM pin sets output stage current. The HBW pin sets global loop bandwidth. A standard QSOP IC package has a pin spacing of 0.635 mm.

The illustrative package shape and orientation are small and user-friendly for printed circuit board (PCB) layout for applications such as power-over-Ethernet (Poe) applications.

The pins 512 and common mode suppression circuit are configured to enable programmable control. In contrast, a standard choking scheme that is implemented using a magnetic device has an active choke functionality that is determined by characteristics of the magnetic device. An end user has no capability to change functionality other than to physically change the magnetic device. In contrast, the illustrative network device has a soft or programmable capability to adjust choking of the device. Accordingly, the illustrative network device 500 has an active choke functionality that differs from a passive choke by virtue of programmability and changeability that enable a user or customer to trade-off power for noise suppression. The active choke functionality enables increased flexibility once the device is produced or manufactured. If the device is in production and a problem or possible is found, software can be changed to fix the emission problem or improve functionality, as opposed to physically changing hardware.

In the illustrative example, the network device 500 includes a circuit that does not supply a driving functionality but does include two interfaces that have a differential line and draw power from a supply while spreading common mode noise.

The network device 500 thus includes an interface for a differential pair of signals, which includes pins for differential signaling except that functionality is open circuit to differential. The circuit does not affect the differential, but only affects common mode.

In other embodiments, various numbers of communication ports can be implemented. A single communication port can be implemented, for example a discrete configuration or a single-port magjack integration. Other implementations can include multiple communication ports, for example a multi-port extension in switch systems in either discreet or magjack integrated configurations.

The pin interface for the network device 500 and the IC package 510 is used in combination with the common mode suppression circuit 502 or active choke implemented in the IC package 510. Each pin set 514A, 514B includes four pins 512 with two power pins and a pair of pins for differential signals that are connected to an active choke that suppresses electromagnetic interference (EMI).

The IC package 510 contains the common mode suppression circuit 202 which functions as a shunt choke and includes one or more channels, each including differential lines and a power device that creates the shunt choke.

Referring again to FIG. 4, in some embodiments the network device 400 can be implemented as an interface 401 coupled in parallel to differential signal lines 404T, 404R connecting an electronic device 410 and an active device operative at a voltage substantially higher than the electronic device 406. The interface 401 is coupled to an Ethernet transformer 412 and comprises an active common mode suppression circuit 402 that reduces common mode impedance by drawing power for the output devices 438 through a center tap 414 of the Ethernet transformer 412.

The active common mode suppression circuit 402 comprises multiple output devices 410 coupled to a two-stage amplifier gain loop 420 that draws power from the output devices 410 through the center tap 414 of the Ethernet transformer 412 and operates as a high-bandwidth AC-coupled feedback loop that is stable when connected to the transformer 412. The two-stage amplifier gain loop 420 can be controlled by control devices 418 for programmable adjustment.

The common mode suppression circuit 402 can be configured with high differential impedance while maintaining low common mode impedance over a predetermined range of frequencies. The common mode suppression circuit 402 functions as an active shunt choke and thus on the basis of active control enables solution of EMI problems without usage of magnetic devices. In contrast, conventional techniques for handling EMI use magnetics for implementing a series choke device which have the disadvantage of introducing problematic parasitics for very high speed applications, and are also highly expensive and physically large. Thus, the illustrative common mode suppression circuit 402 enables production of a smaller device and, by virtue of implementation as an active circuit, enables improved differential signal performance.

Shunt choke behavior can be implemented inside a device that is a separate block from the interface, for example as a common-mode feedback loop inside an operational amplifier. However, an integrated circuit including a closed loop amplifier design is difficult to attain that has the bandwidth achieved using the shunt choke 402 and also has capability to perform differential signaling. In contrast, the illustrative embodiment the shunt choke 402 is implemented outside and separated from the device 406 thereby improving performance. For example, implementing the shunt choke 402 separate from the device 406 enables usage of ferrite beads to enable matching of the impedance of the differential signal. Also, the configuration of the shunt choke 402 separate from the device 406 produces a better high-frequency signal because the device 406 is physically separated from the interface 401 by some real inductance, minimizing the effect of the series choke.

The feedback loop 420 functions as a high-speed common mode feedback loop that suppresses common mode noise that is generated by current that is steered into a device 406, such as an Ethernet PHY, and into the transformer 412. Inductors in the transformer 412 provide current loading as current is steered out of the PHY which, in the absence of the feedback loop 420, would otherwise generate undesirable common mode noise.

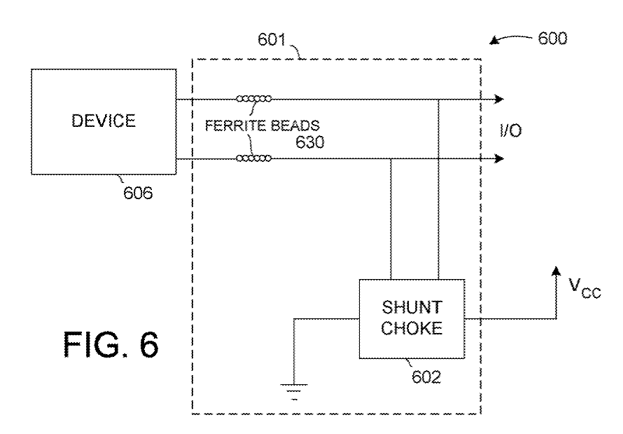

Referring to FIG. 6, a schematic block diagram depicts another embodiment of a network device 600 that implements active electromagnetic interference (EMI) suppression. The network device 600 comprises an active common mode suppression circuit 602 coupled in parallel to a differential pair of signal lines 604T, 604R coupled to an electronic device 606 in which the active common mode suppression circuit 602 is configured for programmable adjustment.

The active common mode suppression circuit 602 can comprise a high-bandwidth AC-coupled feedback loop that is stable when connected to a transformer. The illustrative device 600 is an example embodiment that does not have a transformer coupling to the line, such as would be the case for a Universal Serial Bus (USB) line. In the USB case, the device core is typically either a Class-A or Class-AB output stage as shown in the embodiment depicted in FIG. 7. In contrast, FIG. 6 illustrates that the common-mode suppression technique can be applied to any differential signal system in which EMI could be a problem. The active choke enables a much improved low and mid-band suppression than can be attained through use of magnetic chokes. A suitably designed common mode suppression circuit or shunt choke can achieve a common-mode rejection that exceeds 60 dB, a far better performance than can be attained using magnetics.

The illustrative network device 600 is shown further comprising ferrite beads 630, typically small, low-cost components that can improve EMI filtering performance. The ferrite beads 630 and impedance of the choke 602 can be selected to create a very good high-frequency EMI filter in addition to the lower frequency, mid-band frequency performance that the shunt choke 602 alone can produce. The interface 601, including ferrite beads 630 and the shunt choke 602, uses the ferrite beads 630 and impedance to tune out capacitive loading that is created. Although an ideal differential load cannot be attained, the interface 601 does present some capacitive load generally on the circuit. The ferrite bead 630 is selected to mitigate detrimental impedance effects. For high-speed differential signaling applications, capacitive loading causes impedance looking into the device to be skewed, causing distortion in the received signal. Addition of ferrite beads 630 to the circuit can correct the impedance level and ensure maximum power transfer. Thus, the ferrite beads 630 can be implemented to address loading that is presented with a series choke.

Referring to FIG. 7, a schematic circuit diagram illustrates a common mode suppression circuit with additional detail of the circuit and further description of the signal path. In an illustrative embodiment a communication device 700 may be specified to include a Class A driver that operates a common mode suppression circuit coupled to Vcc and ground lines supplying the Ethernet physical layer (PHY). The communication device is a network device 700 comprising an interface 702 coupled in parallel to transmit and receive differential signal lines 704T, 704R connecting an Ethernet physical layer (PHY) module 706 and a network connector operative at a voltage substantially higher than the PHY module 706. The interface 702 comprises a two-stage amplifier gain loop 708 whereby common mode noise is suppressed, in an example embodiment by at least 40 dB in a frequency range from 100 kHz to 30 MHz. The two-stage amplifier gain loop 708 comprises a Class A output stage 710 coupled between the Ethernet PHY and a first stage preamplifier 712 that is capacitively-coupled at input and output terminals.

FIG. 7 illustrates a circuit diagram of the common mode suppression circuit 702 with additional detail of the circuit and further description of the signal path. Transmit and receive signal lines TRD+ and TRD− are coupled to output terminals of an Ethernet PHY integrated circuit chip. Transistors 714P, 714N in the Class-A output stage 710 include NMOS transistors 714N coupled between ground and the TRD pins. In the illustrative common mode suppression circuit 702, no active devices are coupled between the power source Vcc and the output lines. The Class A design is a one-sided, open-drain configuration. The illustrative common mode suppression circuit 702 includes capacitors that operate as common mode sampling capacitors 716. Signal cm_in is a common mode signal is input to the preamplifier 712. The preamplifier 712 drives the output stage 710. The loop 708 is closed by the capacitors 716. Preamplifier 712 is also coupled into a low frequency bias loop or direct current (DC) control loop 718 which includes a preamplifier DC (PREDC) amplifier 720 that functions as a reference amplifier and sets the reference DC voltage. Preamplifier 712 passes an output signal to a preamplifier output node (PRE_OUT) which is separated from an output stage input node (OS_IN) by a signal path capacitor 722 on a capacitively-coupled signal path. A resistor 724 and variable capacitors 726 form a compensation network 728 and passes to a node ncp, ncn between transistors 714P, 714N.

The illustrative network device 700 thus comprises an interface 702 coupled in parallel to transmit and receive differential signal lines 704T, 704R connecting an Ethernet physical layer (PHY) module 706 and a network connector operative at a voltage substantially higher than the PHY module 706. The interface 702 comprises a two-stage amplifier gain loop 708, a preamplifier loop 730 coupled to the two-stage amplifier gain loop 708, a low frequency bias loop 718 coupled to the preamplifier loop 730, a DC filter 732 coupled to the low frequency bias loop 718, and common mode sampling capacitors 716 coupled from an input terminal to the preamplifier loop 730 to transmit and receive data (TRD±) lines to the Ethernet PHY 706. The DC filter 732 and the common mode sampling capacitors 716 are configured to set low frequency bias bandwidth.

The shunt architecture 702 is not in a series path of the transmit/receive differential signals but rather is in a parallel path with the signals. The parallel or shunt structure facilitates noise elimination. The communication signal includes two component signal types, a common mode signal and a differential signal. The differential signal is the desired, information-carrying signal that is sought to be communicated on the signal line. The common mode signal is the noise signal is desired to be prevented from passing down the line. The series connection is susceptible to the risk that both the common mode and the differential signals are processed, resulting in possible distortion of the desired differential component. In contrast, the parallel shunt configuration avoids processing of the differential mode signal, improving differential distortion performance at lower cost.

The active common mode suppression circuit 702 is configured to terminate common mode impedance over the Ethernet signal frequency range, for example typically in a range from about 100 kHz to 100 MHz range.

In some embodiments, the active common mode suppression circuit 702 can be configured to terminate common mode impedance over an Ethernet signal frequency range whereby common mode noise is suppressed by at least 40 dB from 100 kHz to 30 MHz. The active common mode suppression circuit 702 forms a loop that creates a second-order roll-off in common mode noise suppression at frequencies above 10 kHz.

In some embodiments, the active common mode suppression circuit 702 is configured in a Class A architecture that matches Ethernet PHY line drivers whereby the Ethernet PHY controls output line signal common mode direct current (DC) voltage. The Class-A architecture enables complete control on the output (line signal TRD±) common mode DC voltage by the Ethernet PHY 706.

The active common mode suppression circuit 702 and the Ethernet PHY 706 may be manufactured using the same fabrication process and voltage. Accordingly, the common mode noise suppression circuit 702 may be fabricated in the same low voltage process as the Ethernet PHY 706. In contrast, a Class AB type of design may impose a 5 volt fabrication process of more than 5V in contrast to typical 3.3V technologies. The illustrative configurations may be suitable for any current or future fabrication processes, voltages, and technologies.

The two-stage amplifier gain loop 708 enables high common mode suppression performance. For example in some particular configurations, the active common mode suppression circuit 702 may comprise a two-stage amplifier gain loop 708 whereby common mode noise is suppressed by at least 40 dB, for example from 100 kHz to 30 MHz.

An example implementation of the common mode suppression circuit 702 may be configured so that at zero decibels (dB) on the magnitude axis, nothing is rejected or suppressed. A small amount of peaking at about 3 dB occurs at a frequency of about 5 kHz that is essentially immaterial to functionality. A sharp second order roll-off may begin at about 10 kHz and at approximately 100 kHz, the signal may be reduced substantially by approximately −40 dB or more so that at 100 kHz the common mode noise is rejected by 48 dB by the illustrative common mode suppression circuit 702. From 100 kHz to about 10 MHz, the signal may remain below −40 dB then begins to rise and at about 100 MHz. Various standards of performance may be desired but in one embodiment, suppression is most intended for a range from 100 kHz to 100 MHz. Typically, the greatest conductive electromagnetic interference (EMI) difficulty arises in the 100 kHz to 30 MHz range, the range for which performance is optimized in the illustrative common mode suppression circuit 702. The illustrative common mode suppression circuit 702 exceeds a rejection specification of 40 dB in the selected range. In summary, a particular implementation may reject from 0 to 40 dB in a band between 10 kHz to 100 kHz, have rejection greater than 40 dB in a band from 100 kHz to 30 MHz, and have over 30 dB rejection from 30 MHz to 100 MHz.

In some embodiments, the active common mode suppression circuit 702 comprises a Class-A output stage 710 coupled between the Ethernet PHY 706 and a first stage preamplifier 712. The first stage preamplifier 712 and the Class A output stage 710 form a two-stage amplifier gain loop 708. The first stage preamplifier 712 is completely AC-coupled to the system at both input (CM_IN) and output (PRE_OUT) terminals. The preamplifier 712 is capacitively-coupled to the TRD loop and is capacitively-coupled to the output stage 710 because neither the range of magnitude of the output common mode nor the voltage level at the TRD node is known. Therefore the two-stage gain loop 708 is enabled to float. On the output side of the loop 708, the common mode suppression circuit 702 supplies both a bias control which is a separate low frequency bias (DC) control signal, and an alternating current (AC) signal. The AC signal is capacitively-coupled on a separate path, depicted as an output stage bias (OS_BIAS) path, which sets DC biasing for the output stage 710. The preamplifier 712 floats and is capacitively-coupled with respect to the TRD+ and TRD− signal lines. The preamplifier 712 has a dedicated low frequency bias or DC control loop 718 for both input and output signals.

The illustrative preamplifier loop 730 is designed so that both the AC signal and DC bias are controlled at the same node CM_IN, the node at which the DC amplifier 720 loops back to the input terminals of the preamplifier 712.

In some embodiments, the network device 700 may be configured with the active common mode suppression circuit 702 comprising a two-stage amplifier gain loop 708, a preamplifier loop 730, a low frequency bias loop 718, a DC filter 732, and common mode sampling capacitors 716 coupled from an input terminal (CM_IN) to the preamplifier loop 730 to transmit and receive data (TRD±) lines to the Ethernet PHY 706. The DC filter 732 and the common mode sampling capacitors 716 can be configured to set low frequency bias loop bandwidth. A low frequency bias or DC control loop amplifier 720 for the preamplifier 712 may be designed so that a very low DC loop bandwidth is set by the DC filter 732 by selection of resistor RDC and capacitor CDC and common mode sampling capacitors 716 on the node Cm_in. Accordingly, the two-stage amplifier gain loop 708 progresses from control by the DC amplifier 720 to the AC portion of the circuit at the output stage 710 at increasing frequency with a transition at about 10 kHz between the low frequency bias by the DC loop 718 and high frequency bias at the output stage 710. Essentially no common mode rejection is present below about 10 kHz because the low frequency bias of the DC loop 718 takes over at lower frequencies. Thus, the active common mode suppression circuit 702 is configured to transition from direct current (DC) control to alternating current (AC) control at a sufficiently low frequency that AC performance begins at approximately 10 kHz, attaining excellent AC performance beginning at 10 kHz.

The DC filter 732 may be configured to create resonance in the common mode suppression transfer function in a range approximately between 100 kHz and 30 MHz, enabling very high common mode noise suppression by at least approximately 40 dB and substantially reducing conductive emissions in a band approximately between 100 kHz and 30 MHz. The DC filter 732 is a resistor-capacitor circuit in the DC loop 718 coupled to the output terminal of the PREDC amplifier 720. The R_{DC}C_{DC} circuit that forms the DC filter 732 in combination with common mode sampling capacitors 716 comprise a complete AC impedance at node CM_IN. The DC filter 732 and capacitors 716 set resonance to create the very sharp roll-off in the frequency response to attain common mode rejection of 40 dB to 60 dB in the bandwidth of interest, 100 kHz-30 MHz.

Low frequency bias or DC control bias at multiple nodes including CM_IN node at the input terminal to the preamplifier loop 730, PRE_OUT node at the output terminal of the preamplifier 712, and OS_IN node at the input terminal to the output stage 710 can all be set independently. Independent setting of DC bias at the multiple nodes enables independent system optimization at each of the nodes to any desired DC level because the nodes are AC decoupled. OS_IN node is the bias node for the output stage Class A amplifier output terminal and the DC level set in the OS_IN bias path is controlled independently of any other node. At the PRE_OUT node at the output of the preamplifier 712, the DC level is controlled by the DC_REF path on the PREDC amplifier 720 and can be set for maximum performance of the preamplifier 712. The nodes are decoupled because bias for maximum performance of the preamplifier 712 may not match bias for maximum performance of the output stage 710. Input bias of the preamplifier 712 is set by the Cm_ref node to enable optimization to any bias that produces maximum performance without dependence on the other nodes.

In some embodiments, an output stage bias loop 734 coupled between the preamplifier loop 730 and the Class A output stage 710 may be configured to set DC current bias in the Class A output stage 710. The output stage bias loop 734 is separate from the preamplifier loop 730 and operates to set the DC current bias in the Class-A output stage 710 through the OS_BIAS path, enabling very good control on the DC current through the output stage 710.

The two stages of the two-stage amplifier gain loop 708 comprise the Class-A output stage 710 and the preamplifier loop 730. The Class-A output stage 710 is configured with separate DC bias and AC signal paths for output bias control. The preamplifier loop 730 is configured with an AC-coupled output terminal. A programmable loop compensation technique may be implemented to manage a large variety of output load conditions. Because the common mode suppression circuit 702 is designed for usage with various Ethernet PHY components, the capacitive loading at the output to the Ethernet PHY is not under control of the common mode suppression circuit design. The Ethernet PHY capacitive loading may be very small or highly capacitive, for example a range from 5 pF to 25 pF or even larger ranges. Thus, the common mode suppression circuit 702 may be configured with a variable compensation loop that assists operation across a wide range of frequencies and output loading.

Loop compensation capacitors 726 may be coupled to the Class-A output stage 710 reduce loading at the transmit and receive data (TRD±) nodes. In another configuration, the compensation capacitors may be connected directly to the output nodes TRD±. Connecting the loop compensation capacitors 726 at the NCP-NCN node as depicted may be desirable to avoid increasing loading on the Ethernet PHY 706, enabling a low capacitance design at the cost of a simple change in load size.

The output stage 710 may be configured to roll-off at frequency bands at which the preamplifier loop 730 remains at high gain.

Low differential capacitance at the output of the common mode suppression circuit 702 is implemented to avoid degrading of Ethernet signaling performance as well as to maintain good return loss performance.

The output stage 710 may be configured with a selected Unity Gain Bandwidth (UGBW) and the preamplifier loop configured with a UGBW at approximately four times the output stage UGBW whereby the output stage output signal rolls-off at frequency bands at which the preamplifier loop remains at high gain. In the illustrative example, the common mode suppression circuit 702 is terminated with a common mode impedance R_{T}, for example 50 Ω, with Ethernet line termination and approximately 20 pF of capacitive load, setting the primary pole for the loop at 160 MHz. The common mode suppression circuit design enables a compensation technique to cause the output stage to roll-off faster than the preamplifier stage even in presence of Miller compensation in which a capacitor added across an inverting amplifier appears much larger from the input of the amplifier. The compensation technique maintains sufficient common mode noise suppression performance at 100 MHz frequency. The common mode suppression circuit design enables the output stage to roll-off while the input stage remains at high gain.

In some embodiments, the common mode suppression circuit 702 may further comprise an output stage gate reference node (OS_GATE) coupled to the Class A output stage 710 that is configured to be software programmable to accommodate very large signal swings to a V_{CC} range in 10 Base-T to 1000 Base-T designs with variable output DC control. In an illustrative embodiment, the output DC control is set by an inductor L_{S} or the Ethernet PHY V_{CC}. The output node can have a large signal swing, for example in a range of approximately 0.85V to 5.0V. Therefore the output stage 710 is designed to tolerate such signal swings.

The low frequency bias loop 718 may be configured to set both input and output common mode voltage of the preamplifier loop 730 whereby input common mode control is set by a sum of preamplifier gain and low frequency bias loop gain and output common mode control is set by low frequency bias loop gain.

Biasing for the overall system may be designed to enable excellent noise rejection from the power supply paths. For example referring to FIG. 3, noise may be passing through the power supply Vcc path 330 and through inductors Lₛ, for example 220 uH, and the integrated circuit chip for the interface may also generate a system power supply Vcc. Accordingly, the common mode suppression circuit 302 may be designed with very good power supply rejection capability to prevent passing power supply noise to the output stage. Thus biasing of the overall system is designed to enable excellent noise rejection from the power supply as well as other noise sources.

Referring again to FIG. 7, the common mode suppression circuit 702 may be designed to absorb common mode noise from Ethernet signaling pairs TRD+ and TRD−, preventing noise to pass to the signal line from Ethernet equipment, thereby controlling electromagnetic interference (EMI) emissions, as well as preventing noise passing in from the signal line to impact Ethernet equipment (EMI immunity). Thus, the illustrative common mode suppression circuit 702 can be designed for EMI emission control to avoid passing noise generated in the interface and the Ethernet PHY 706 to pass out to the signal line, and for EMI immunity to prevent noise on the signal line from passing to the interface and Ethernet PHY 706.

The illustrative common mode suppression circuit 702 may be configured to operate by passing signals from a relatively high voltage technology at a network connector to a relatively low voltage technology at an Ethernet physical layer (PHY) module 706. The common mode suppression circuit 702 forms a low impedance pathway from an output terminal of the PHY module 706 to ground that absorbs a common mode noise portion of the signals while enabling a differential portion of the signals to pass. The common mode suppression circuit 702 also suppresses common mode noise using a two-stage amplifier gain loop 708.

The common mode suppression circuit 702 may further be designed to apply a second order roll-off in a range from approximately 10 kHz to 100 kHz and suppress common mode noise by at least 40 dB in a range from approximately 100 kHz to 30 MHz and by at least 30 dB in a range from approximately 30 MHz to 100 MHz.

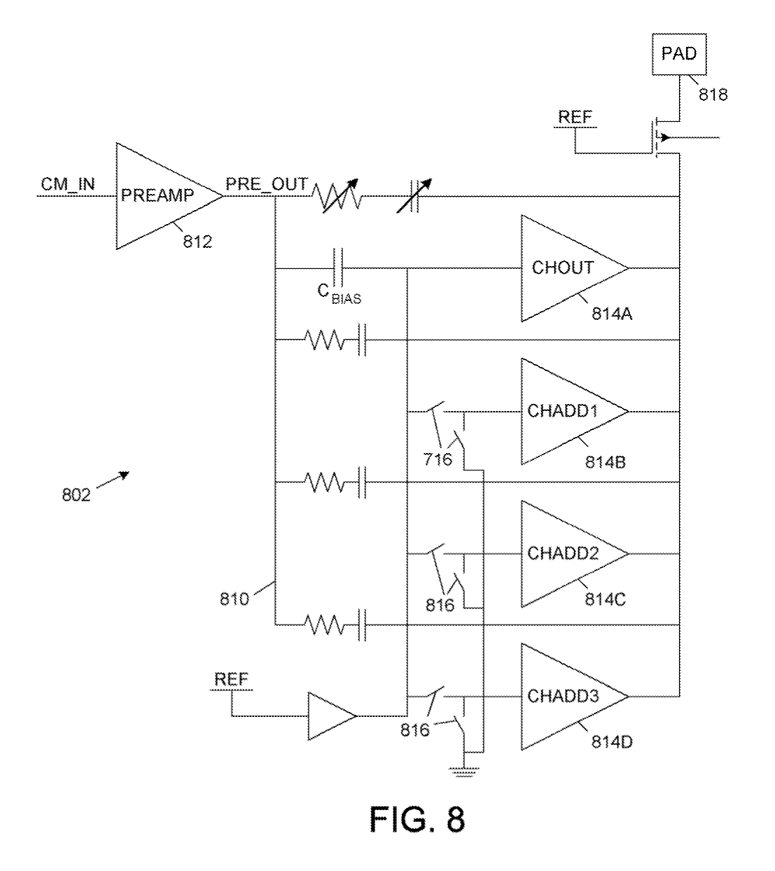

Referring to FIG. 8, a schematic block and circuit diagram illustrates an embodiment of a common mode suppression circuit 802 including a programmable output stage 810. In an illustrative common mode suppression circuit, the output stage 810 may be software programmable to meet different EM immunity requirements and specifications for different applications. For example, the multiple independent bias nodes in the common mode suppression circuit effectively result in formation of four output stage amplifiers 814A-D that are under software control. Some applications may call for different levels of EMI rejection capability. The four output stage amplifiers 814A-D comprise four segments. The multiple segments enable absorption of more electromagnetic interference (EMI). Different applications of the network device may be configured for different absorption capability. The multiple segments may be individually programmed using programmable switches 816. The four segments are all connected to the transmit and receive lines TRD±.

The illustrative common mode suppression circuit 802 has a two-stage architecture with a preamplifier 812 and the Class A output stage 810 that enables a design to be constructed in the same process and voltage as the Ethernet PHY, for example 3.3V or 2.5V.

The illustrative preamplifier 812 may be completely AC-coupled. The output common mode can vary largely based on the choice of inductive termination. Accordingly, common mode noise can be reduced by AC coupling the input stage formed by the preamplifier 812. The Class-A driver has separate DC and AC paths for output bias control. Accordingly, the preamplifier output is also AC coupled. A separate DC feedback loop is connected around the preamplifier 812 that conflicts with the AC common-mode rejection loop.

The illustrative output stage 810 may be constructed with three blocks including a choke output block (CHOUT) 814A, a plurality of choke adder blocks (CHADDn) 814B-D, and a choke pad block (PAD) 818. The output stage 810 may be implemented with a wide output swing specification at a final output node, for example between 0.85V and 2.5V.

The current control capability of the output stage 810 may be implemented to source and sink large common mode noise currents according to various EMI immunity testing standards. In an illustrative embodiment, the output stage can be designed for current in a range from 12 mA to 30 mA in a programmable range of 12/18/24/30 mA. A default may be implemented as 12 mA per node. The output device is a fixed electrostatic discharge (ESD) device. Additional amplifiers 814A-D are summed into the source node.

Stability of the output stage 810 can be implemented with Miller compensation in the input device. Class A stage gain drops as common mode load impedance becomes resistive 25 Ω. The preamplifier 812 maintains a wide bandwidth and supplies high frequency gain.

Terms “substantially”, “essentially”, or “approximately”, that may be used herein, relate to an industry-accepted tolerance to the corresponding term. Such an industry-accepted tolerance ranges from less than one percent to twenty percent and corresponds to, but is not limited to, component values, integrated circuit process variations, temperature variations, rise and fall times, and/or thermal noise. The term “coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. Inferred coupling, for example where one element is coupled to another element by inference, includes direct and indirect coupling between two elements in the same manner as “coupled”.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims. For example, various aspects or portions of a network interface are described including several optional implementations for particular portions. Any suitable combination or permutation of the disclosed designs may be implemented.

What is claimed is:

1. A network device comprising:
an interface coupling an electronic device to a differential pair of signal lines; and
an active common mode suppression circuit coupled to the interface in parallel to differential signal lines of the electronic device.

2. The network device according to claim 1 further comprising:
at least one active output device coupled to the interface;
a transformer coupled to the electronic device and comprising a center tap and windings; and
the active common mode suppression circuit configured to draw power from the at least one active output device through the center tap of the transformer.

3. The network device according to claim 2 further comprising:
the active common mode suppression circuit configured to reject electromagnetic interference (EMI) noise related in part to common mode noise through the transformer.

4. The network device according to claim 1 further comprising:
the active common mode suppression circuit configured to reduce common mode impedance and short-circuiting common-mode energy to a system ground.

5. The network device according to claim 1 further comprising:
the active common mode suppression circuit comprising a high-bandwidth AC-coupled feedback loop that is stable when connected to a transformer and draws a predetermined amount of current unless a common mode disturbance occurs at a frequency that is higher than a predetermined normal range of frequencies, the feedback loop controlled to respond to the common mode disturbance with negative feedback that suppresses the disturbance.

6. The network device according to claim 1 further comprising:
the interface is an Ethernet interface that couples a differential pair network connector to an Ethernet physical layer (PHY).

7. The network device according to claim 1 further comprising:
the interface is a generic differential interface selected from a group consisting of Universal Serial Bus (USB), Institute of Electrical and Electronics Engineers (IEEE) 1394, High-Definition Multimedia Interface (HDMI), DisplayPort standard as defined by Video Electronics Standards Association (VESA), Digital Visual Interface (DVI), and audio signals.

8. The network device according to claim 1 further comprising:
a package comprising a plurality of integrated circuit (IC) pins, the pin plurality arranged as at least one differential pin set comprising a negative power pin (V_{SS}), first and second differential transmit and receive line pins for coupling to the transmit and receive differential signal lines, and a power pin (V_{CC}).

9. The network device according to claim 1 further comprising:
the active common mode suppression circuit configured for programmable adjustment.

10. The network device according to claim 1 further comprising:
the active common mode suppression circuit configured to suppress common mode noise generated as a result of differential-to-common mode conversion due to transformer imperfections.

11. The network device according to claim 1 further comprising:
the active common mode suppression circuit comprising a differential amplifier that performs alternative current (AC) coupling sensing and controls driving of signals onto a differential pair of signal lines through a center tap of an Ethernet transformer for current absorption and noise immunity.

12. The network device according to claim 1 further comprising:
the active common mode suppression circuit comprising a differential amplifier that performs alternative current (AC) coupling sensing and controls driving of signals onto a differential pair of signal lines through a center tap of an Ethernet transformer, enabling toleration of a wide differential signal swing.

13. The network device according to claim 1 further comprising:
the interface comprises n-channel metal oxide semiconductor (NMOS) devices, p-channel metal oxide semiconductor (PMOS) devices, or a combination of NMOS and PMOS devices.

14. A network device comprising:
an interface coupled in parallel to differential signal lines connecting an electronic device and a differential pair operative at a voltage substantially higher than the electronic device, the interface coupled to an Ethernet transformer and comprising an active common mode suppression circuit that reduces common mode impedance by drawing power through a center tap of the Ethernet transformer.

15. The network device according to claim 14 further comprising:
the active common mode suppression circuit comprising a plurality of output devices coupled to a two-stage amplifier gain loop that draws power from the output devices through the center tap of the Ethernet transformer.

16. The network device according to claim 14 further comprising:
the active common mode suppression circuit comprising a high-bandwidth AC-coupled feedback loop that is stable when connected to a transformer and draws a predetermined amount of current unless a common mode disturbance occurs at a frequency that is higher than a predetermined normal range of frequencies, the feedback loop controlled to respond to the common mode disturbance with negative feedback that suppresses the disturbance.

17. The network device according to claim 14 further comprising:
the active common mode suppression circuit configured for programmable adjustment.

18. A network device comprising:
a package comprising a plurality of integrated circuit (IC) pins, the pin plurality coupled to an active mode suppression circuit and arranged as at least one differential pin set comprising a negative power pin (V_{SS}), first and second differential transmit and receive line pins for coupling to the transmit and receive differential signal lines, and a power pin (V_{CC}).

19. The network device according to claim 18 further comprising: the package comprising a Quarter-size Small-Outline (QSOP) package.

20. The network device according to claim 18 further comprising:
the active common mode suppression circuit configured for programmable adjustment.

21. A network device comprising:
an active common mode suppression circuit coupled in parallel to a differential pair of signal lines coupled to an electronic device and configured for programmable adjustment.

22. The network device according to claim 21 further comprising:
the active common mode suppression circuit comprising a high-bandwidth AC-coupled feedback loop that is stable when connected to a transformer and draws a predetermined amount of current unless a common mode disturbance occurs at a frequency that is higher than a predetermined normal range of frequencies, the feedback loop controlled to respond to the common mode disturbance with negative feedback that suppresses the disturbance.

23. A method of operating a network device comprising:
coupling an electronic device to a differential pair of signal lines;
coupling an active common mode suppression circuit in parallel to differential signal lines of the electronic device.

24. The method according to claim 23 further comprising:
drawing power from active common mode suppression circuit output devices that drive signals onto the differential pair of signal lines through a center tap of an Ethernet transformer whereby common mode impedance is reduced.
